(19) United States
(12) Patent Application Publication
(10) Pub. No.: US 2010/0193937 A1
(43) Pub. Date: Aug. 5, 2010

(54) SEMICONDUCTOR MODULE

(75) Inventors: Masayuki Nagamatsu, Osaka (JP); Yasuhiro Kohara, Osaka (JP); Ryosuke Usui, Osaka (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 12/697,803

(22) Filed: Feb. 1, 2010

(30) Foreign Application Priority Data
Jan. 30, 2009 (JP) 2009-020985

(51) Int. Cl. H01L 23/48

(52) U.S. Cl. 257/693; 257/E23.01

(57) ABSTRACT

A wiring layer including external connection regions is provided on a main surface of an insulating resin layer on a side opposite to that of a semiconductor device mounting face. The wiring layer is coated with a protection layer. An opening is provided to the protection layer such that each external connection region is exposed. Each external connection region has a curved surface recessed toward the insulating resin layer side. The entire area of each opening is filled with a solder ball for mounting a substrate, and the recess of each external connection region is filled with the solder ball, thereby connecting each solder ball to the intermediate layer.

This application is based upon and claims the benefit of priority from the prior Japanese Patent Applications No. 2009-020985, filed Jan. 30, 2009, the entire contents of which are incorporated herein by reference.

### BACKGROUND OF THE INVENTION

1. Field of the Invention

The present invention relates to a semiconductor module having a structure in which a semiconductor device is mounted on an device mounting substrate including a base material and a wiring layer, and a mobile device mounting the semiconductor module.

2. Description of the Related Art

As improvement of the functions of portable electronic devices such as cellular phones, PDAs, DVCs, and DSCs accelerates, in order to provide such electronic products acceptable to the market, there is a need to form such electronic products with a reduced size and with a reduced weight. In order to reduce the size and weight thereof, there is a need to provide a highly-integrated system LSI. Also, there is a demand for user-friendly and convenient electronic devices. This requires the LSIs employed in such electronic devices to have improved functions and improved performance. Accordingly, such highly-integrated LSI chips involve an increased number of I/O ports (the number of input/output ports), together with the strong demand for such LSI chips to have a package with a reduced size. In order to satisfy both the desired conditions, there is a strong demand for the development of a semiconductor module suitable for mounting semiconductor components on a substrate with high packaging density. In order to meet such a demand, various packaging techniques, which are referred to as CSP (Chip Size Package), are being developed.

Together with the demand for reduced-size semiconductor modules, there is also a demand for further improving the connection reliability in the step for mounting a semiconductor module on a substrate. As a factor that affects the connection reliability of the semiconductor module, reliability in the connection between external connection electrodes (in general, solder balls) used to mount the substrate and a wiring layer of the semiconductor module is known. With regard to conventional semiconductor modules, there is room for further improving the connection reliability of the external connection electrodes thereof.

### SUMMARY OF THE INVENTION

The present invention has been made in order to solve such a problem. Accordingly, it is a general purpose of the present invention to provide a semiconductor module having the advantage of improved connection reliability of external connection electrodes.

An embodiment of the present invention relates to a semiconductor module. The semiconductor module comprises: an device mounting substrate which comprises a base material, a first wiring layer provided on one main surface of the base material, a second wiring layer provided on the other main surface of the base material, and a protection layer arranged so as to coat the other main surface of the base material, and provided with an opening through which an external connection region of the second wiring layer is exposed; and a semiconductor device mounted on the one main surface side of the base material. Furthermore, the surface of the second wiring layer in the external connection region is positioned closer to the base material side than the bottom of the protection layer on the base material side is to the base material side.

Such an embodiment increases the contact area where each external connection electrode is in contact with the corresponding external connection region and the protection layer of the semiconductor module when the external connection electrodes are mounted. Thus, such an arrangement increases the strength of the connection between each external connection electrode and the corresponding external connection region and the protection layer, thereby improving the connection reliability of the external connection electrodes.

With such an embodiment, a space may be formed between the bottom of the protection layer on the base material side and the surface of the second wiring layer along the perimeter of the opening. Also, the external connection region may have a larger area than that of the opening. Also, an electro-conductive intermediate layer may be formed in the external connection region. Also, the surface of the intermediate layer may be positioned closer to the base material side than the bottom of the protection layer on the base material side is to the base material side.

Another embodiment of the present invention relates to a semiconductor module. The semiconductor module comprises: a base material; a first wiring layer provided on one main surface of the base material; a second wiring layer provided on the other main surface of the base material; a protection layer arranged so as to coat the other main surface of the base material, and provided with an opening through which an external connection region of the second wiring layer is exposed; an external connection electrode arranged in the external connection region of the second wiring layer; and a semiconductor device mounted on the one main surface side of the base material. Furthermore, the surface of the second wiring layer in the external connection region is positioned closer to the base material side than the bottom of the protection layer on the base material side is to the base material side.

Such an embodiment increases the contact area where each external connection electrode is in contact with the corresponding external connection region and the protection layer of the semiconductor module. Thus, such an arrangement increases connection strength between each external connection electrode and the corresponding external connection region and the protection layer of the semiconductor module, thereby improving connection reliability of the external connection electrodes.

With such an embodiment, a space may be formed between the bottom of the protection layer on the base material side and the surface of the second wiring layer along the perimeter of the opening. Also, the space thus formed may be filled with the external connection electrode. Also, an intermediate layer having higher wettability for the external connection electrode than that of the second wiring layer may be provided between the external connection electrode and the wiring layer.

Yet another embodiment of the present invention relates to an arrangement which mounts a semiconductor module according to any one of the above-described embodiments.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional diagram which shows a configuration of a semiconductor module according to an embodiment 1;

FIG. 2 is an enlarged view of principal components showing a connection structure whereby a solder ball is connected to a wiring layer in an external connection region;

FIGS. 3A to 3D are a cross-sectional manufacturing step diagram which shows a manufacturing method for the semiconductor module according to the embodiment 1;

FIGS. 4A to 4E are a cross-sectional manufacturing step diagram which shows the manufacturing method for the semiconductor module according to the embodiment 1;

FIGS. 5A to 5C are a cross-sectional manufacturing step diagram which shows the manufacturing method for the semiconductor module according to the embodiment 1;

FIG. 6 is a cross-sectional diagram which shows a structure of a semiconductor module according to an embodiment 2;

FIG. 7 is a diagram which shows a configuration of a cellular phone including a semiconductor module according to an embodiment; and

FIG. 8 is a partial cross-sectional view of the cellular phone shown in FIG. 7.

### DETAILED DESCRIPTION OF THE INVENTION

The invention will now be described by reference to the preferred embodiments. This does not intend to limit the scope of the present invention, but to exemplify the invention.

Description will be made below regarding embodiments according to the present invention with reference to the drawings. The same or similar components are denoted by the same reference numerals in the drawings, and redundant description thereof will be omitted as appropriate.

### Embodiment 1

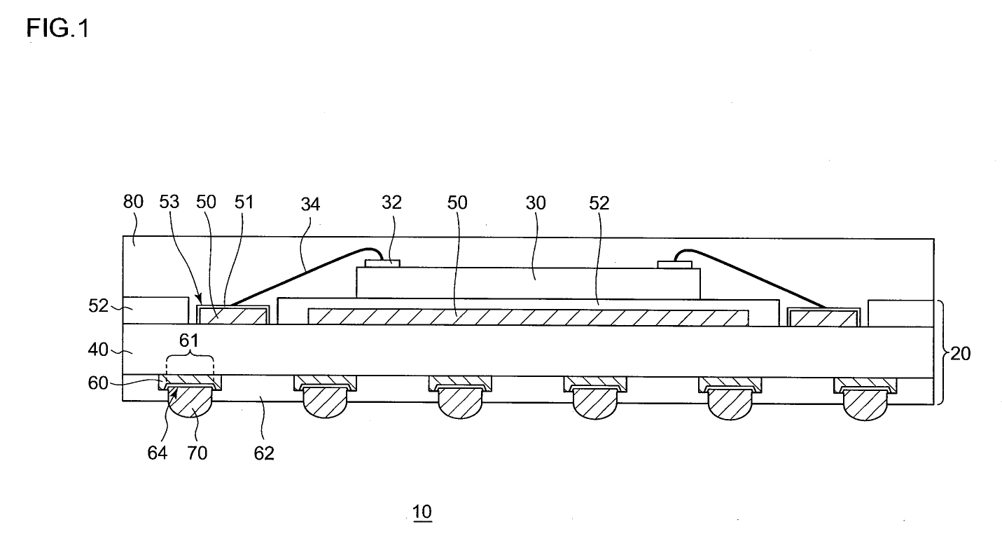

FIG. 1 is a cross-sectional diagram which shows a structure of a semiconductor module according to an embodiment 1. A semiconductor module 10 includes an device mounting substrate 20 and a semiconductor device 30. In the present embodiment, the semiconductor device 30 is connected to the device mounting substrate 20 by wire bonding.

The device mounting substrate 20 includes: an insulating resin layer 40, a wiring layer 50 and a protection layer 52 provided on one main surface (semiconductor device mounting side) of the insulating resin layer 40, a wiring layer 60, a protection layer 62, and solder balls 70 provided on the other main surface of the insulating resin layer 40.

Examples of materials forming the insulating resin layer 40 include: melamine derivatives such as BT resin, etc., and thermosetting resin such as liquid crystal polymer, epoxy resin, PPE resin, polyimide resin, fluorine resin, phenolic resin, polyamide bismaleimide, etc. From the perspective of improving the heat-releasing performance, the insulating resin layer 40 preferably has high thermal conductivity. Accordingly, the insulating resin layer 40 preferably contains silver, bismuth, copper, aluminum, magnesium, tin, zinc, alloy thereof, or the like, in the form of a filler with high thermal conductivity.

The wiring layer 50 has a predetermined wiring pattern, and is provided to one main surface of the insulating resin layer 40. The wiring layer 50 is formed of an electro-conductive material such as copper or the like. The wiring layer 50 includes substrate electrodes 51 (electrode pads) 51 each of which is used to connect the semiconductor device 30 by wire bonding. The thickness of the wiring layer 50 is 10 to 25 μm, for example. A Ni/Au layer structure 53, which includes a Ni layer and a Au layer laminated onto the surface of the Ni layer, is provided to the surface of each substrate electrode 51.

The protection layer 52 is laminated onto the insulating resin layer 40 and the wiring layer 50. Openings are formed in the protection layer 52 so as to expose each substrate electrode 51. The protection layer 52 protects the wiring layer 50 from being oxidized, and prevents deterioration of the insulating resin layer 40. The protection layer 52 is a photo-solder resist layer, for example. The thickness of the protection layer 52 is 10 to 50 μm, for example.

The wiring layer (rewiring) 60 has a predetermined pattern, and is provided to the other main surface of the insulating resin layer 40. The wiring layer 60 is formed of electro-conductive material such as copper or the like. The wiring layer 60 includes an external connection region 61 used to connect the solder balls (external connection electrodes) 70. The thickness of the wiring layer 60 is 10 to 25 μm, for example.

The wiring layer 50 is electrically connected to the wiring layer 60 by a via conductor (not shown) that passes through the insulating resin layer 40. The via conductor is formed by copper plating, for example.

The protection layer 62 is provided on the other main surface of the insulating resin layer 40 such that it covers the wiring layer 60. The protection layer 62 thus formed protects the wiring layer 60 from being oxidized, and prevents deterioration of the insulating resin layer 40. Openings are provided to the protection layer 62, which allows each solder ball 70 to be mounted in the external connection region 61. Each solder ball 70 is electrically connected to the wiring layer 60 via an intermediate layer 64 described later in the opening formed in the protection layer 62, thereby connecting the semiconductor module 10 to an unshown printed wiring board by means of the solder balls 70. The protection layer 62 is formed of photo-solder resist, for example. The thickness of the protection layer 62 is 10 to 50 μm, for example. Detailed description will be made later regarding the connection portion at which the solder ball 70 is connected to the wiring layer 60.

The semiconductor device 30 is an active element such as IC (integrated circuit), LSI (large-scale integrated circuit), or the like. Device electrodes 32 (electrode pads) are provided to an electrode formation face of the semiconductor device 30. Each device electrode 32 is connected to the corresponding substrate electrode 51 via a wire 34 such as a gold wire or the like.

The semiconductor device 30 is sealed by a seal resin 80, thereby suppressing adverse effects from the external environment. The seal resin 80 can be applied using the transfer mold method, injection mold method, potting method, or dipping method. As the resin material, thermosetting resin such as epoxy resin or the like can be applied using the transfer mold method or the potting method, whereas thermoplastic resin such as polyimide resin, polyphenylene sulfide, etc., can be applied using the injection mold method. Examples of materials forming the solder balls 70 include alloys of Sn and metals such as Ag, Cu, Bi, Zn, In, Au, Sb, Ga, Ge, Pb, etc.

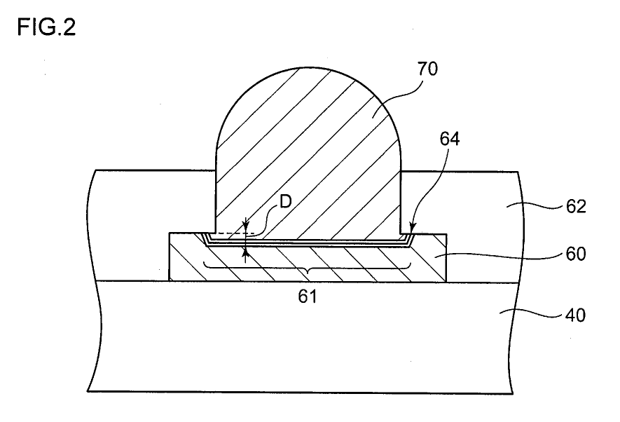

Next, with reference to FIG. 2, detailed description will be made regarding a connection structure whereby the solder ball 70 is connected to the wiring layer in the external connection region 61. FIG. 2 is an enlarged view of the principal components, showing the connection structure whereby the solder ball 70 is connected to the wiring layer 60 in the external connection region 61. It should be noted that the top and bottom in FIG. 2 are the reverse of FIG. 1.

As shown in FIG. 2, the surface of the wiring layer 60 in the external connection region 61 is positioned closer to the insulating resin layer 40 than the bottom face of the protection layer 62 on the insulating resin layer 40 side is to the insulating resin layer 40. In other words, the wiring layer 60 has a curved surface recessed toward the insulating resin layer 40 in the external connection region 61. Furthermore, a space is formed between the bottom face of the protection layer 62 on the insulating resin layer 40 side and the surface of the wiring layer 60, along the perimeter of the opening formed in the protection layer 62. That is to say, the area of the external connection region 61 is larger than that of the opening.

An electro-conductive intermediate layer 64 is provided to the external connection region 61 of the wiring layer 60. In the present embodiment, the intermediate layer 64 is provided in the form of a Ni/Au layer structure. The thickness of the Ni layer that is in contact with the wiring layer 60 is 0.05 to 0.1 μm, for example. Furthermore, the thickness of the Au layer formed on the Ni layer is 0.5 to 1.0 μm, for example. The surface of the intermediate layer 64 is positioned closer to the insulating resin layer 40 side than the bottom of the protection layer 62 on the insulating resin layer 40 side is to the insulating resin layer 40 side. In other words, the thickness of the intermediate layer 64 is smaller than the depth (depth of the recess) D in the external connection region 61, with the surface of the wiring layer 60 surrounding the external connection region 61 as the base of comparison.

Also, the intermediate layer 64 may be provided in the form of a Ni/Pd/Au layer structure. The thickness of the Ni layer that is in contact with the wiring layer 60 is 0.05 to 0.1 μm, for example. Furthermore, the thickness of the Pb layer formed on the Ni layer is 0.05 to 1 μm, for example. Moreover, the thickness of the Au layer formed on the Pb layer is 0.05 to 1 μm, for example. The surface of the intermediate layer 64 is positioned closer to the insulating resin layer 40 side than the bottom of the protection layer 62 on the insulating resin layer 40 side is to the insulating resin layer 40 side, as it is in an arrangement in which the intermediate layer 64 is provided in the form of a Ni/Au layer structure. In other words, the thickness of the intermediate layer 64 is smaller than the depth (depth of the recess) D in the external connection region 61, with the surface of the wiring layer 60 surrounding the external connection region 61 as the base of comparison. It should be noted that the depth D is 1.5 to 3 μm, whether the intermediate layer 64 is provided in the form of a Ni/Au layer structure or a Ni/Pd/Au layer structure.

The entire space of the opening formed in the protection layer 62 is filled by the solder ball 70. Furthermore, the recess in the external connection region 61 is filled by the solder ball 70, thereby connecting the solder ball 70 to the intermediate layer 64 provided so as to correspond to the external connection region 61. Thus, the solder ball 70 penetrates into the space between the bottom of the protection layer 62 and the surface of the intermediate layer 64 along the perimeter of the opening formed in the protection layer 62.

It should be noted that the Ni layer and the Au layer that form the intermediate layer 64 may be melted in the step for providing the solder balls 70 by means of reflow, such that they form an alloy with the solder that forms the solder ball 70. In this case, the intermediate layer 64 is not provided in the form of a Ni/Au layered structure, but is provided as an alloy layer formed of an alloy with Sn, Cu, etc., which are materials that form the solder ball 70 or the wiring layer 69.

### [Manufacturing Method]

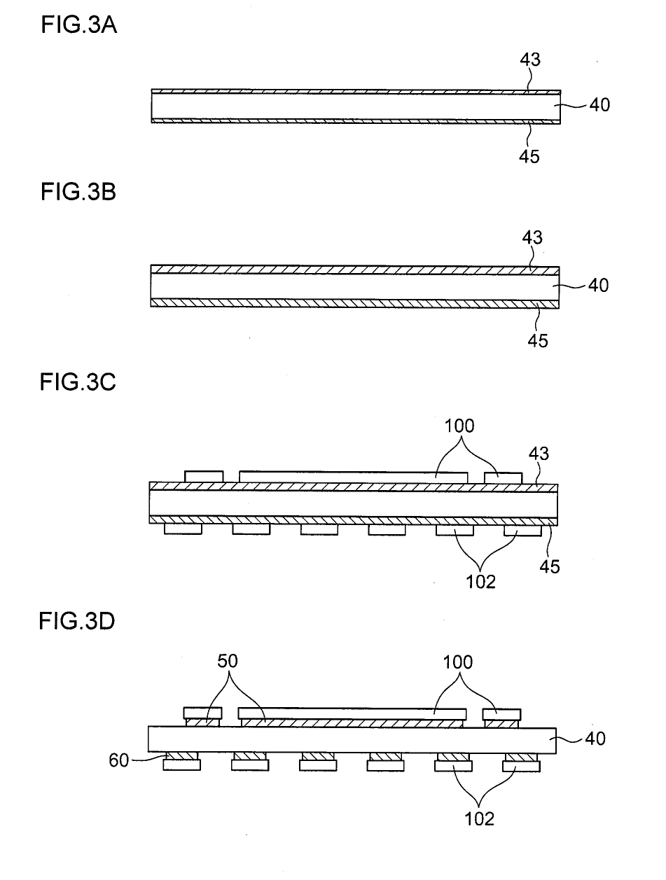

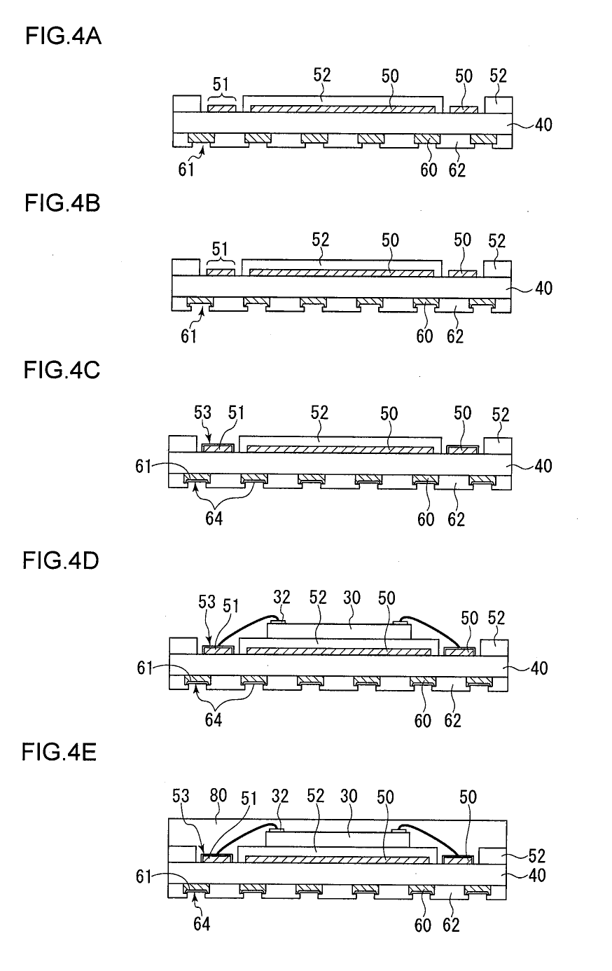

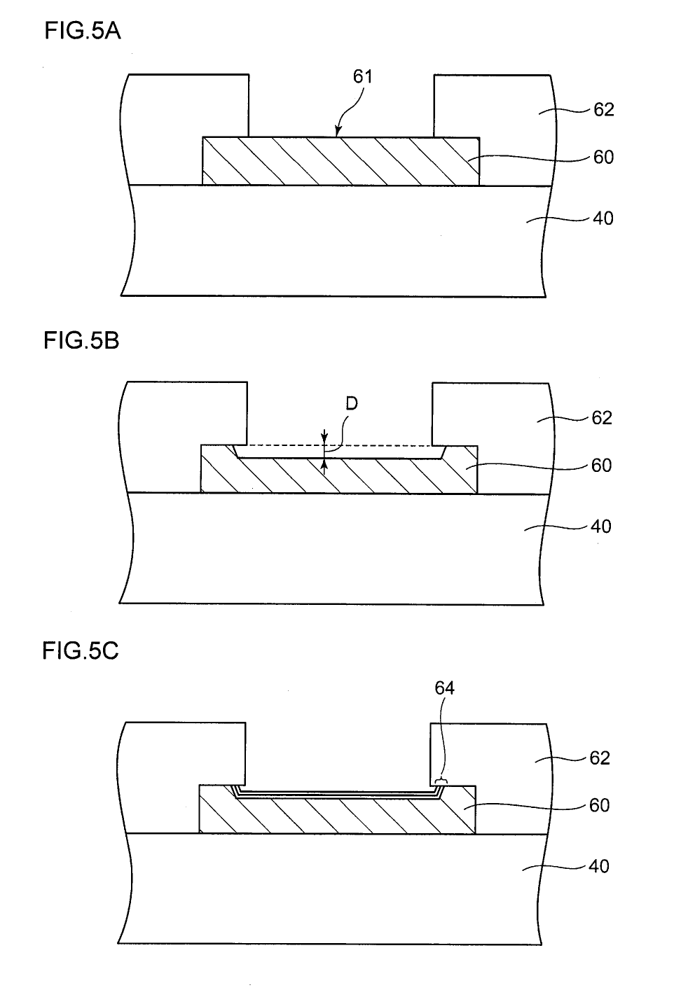

Description will be made below with reference to FIGS. 3 through 5 regarding a manufacturing method for the semiconductor module according to the embodiment 1. It should be noted that FIGS. 5A through 5C are enlarged views of principal components, which correspond to FIGS. 4A through 4C, respectively. It should be noted that the top and bottom in FIGS. 5A through 5C are the reverse of FIGS. 4A through 4C.

First, as shown in FIG. 3A, the insulating resin layer 40 is prepared, to one main surface of which a copper foil 43 has been applied, and to the other main surface of which a copper foil 45 has been applied. The thickness of the copper foils 43 and 45 are each 5 for example.

Next, as shown in FIG. 3B, the thickness of each of the copper foils 43 and 45 is increased up to around 20 μm using the plating method. It should be noted that, in the step for increasing the thickness of the copper foils 43 and 45, via conductors (not shown) are formed at predetermined positions so as to connect the copper foil 43 and the copper foil 45. Specifically, after via holes are formed at predetermined regions of the insulating resin layer 40 and the copper foils 43 and 45 by drilling processing using a drill, laser, or the like, each via hole is filled with copper by electroless plating or electroplating, thereby forming the via conductors. At the same time, the thicknesses of the copper foils 43 and 45, which are provided to the respective main faces, are each increased.

Next, as shown in FIG. 3C, resist films 100 and 102 having predetermined patterns are respectively formed on the copper foils 43 and 45 using a photolithographic method.

Next, as shown in FIG. 3D, wet etching is performed using an etching agent such as aqueous ferric chloride or the like with the resist film 100 as a mask, thereby forming the wiring layer 50 on the one main surface of the insulating resin layer 40. At the same time, wet etching is performed using an etching agent such as aqueous ferric chloride or the like with the resist pattern 102 as a mask, thereby forming the wiring layer 60 on the other main surface of the insulating resin layer 40.

Next, after the resist films 100 and 102 are removed using aqueous sodium hydroxide, a solder resist layer is laminated onto the entire surfaces of both the main surfaces of the insulating resin layer 40 using a laminating apparatus. The thickness of the solder resist layer is 15 μm, for example.

Subsequently, as shown in FIGS. 4A and 5A, using a photolithographic method, openings are formed in the solder resist layer on the one main surface side of the insulating resin layer 40 so as to expose each substrate electrode 51, thereby forming the protection layer 52. In the same way, using a photolithographic method, openings are formed in the solder resist layer on the other main surface side of the insulating resin layer 40 so as to expose each external connection region 61, thereby forming the protection layer 62.

Next, as shown in FIGS. 4B and 5B, the wiring layer 60 exposed in each opening formed in the protection layer 62 is etched by wet etching (soft etching) using a Na₂S₂O₈ solution. The etching depth D is 2 μm, for example. Thus, in the external connection region 61, the wiring layer 60 has a curved surface recessed toward the insulating resin layer 40. Furthermore, the wiring layer 60 positioned below the protection layer 62 along the perimeter of each opening is removed by the soft etching, thereby forming a space between the protection layer 62 and the wiring layer 60. It should be noted that each substrate electrode 51 is soft etched as well.

Next, as shown in FIGS. 4C and 5C, the intermediate layer 64 having a Ni/Au layer structure is formed in the external connection region 61 by electroplating. The requirements for the thickness of the intermediate layer include a requirement that the thickness of the intermediate layer 64 be smaller than the etching depth D shown in FIG. 5D. Furthermore, at the same time as the intermediate layer 64 is formed, the Ni/Au layer structure 53 is formed on the surface of each substrate electrode 51.

Next, as shown in FIG. 4D, the semiconductor device 30 is mounted on the protection layer 52 provided to the element mounting region. An adhesive may be applied between the protection layer 52 and the semiconductor device 30. Subsequently, each device electrode 32 provided to the semiconductor device 30 is wire-bonded to a corresponding substrate electrode 51 using gold wire.

Next, as shown in FIG. 4E, the semiconductor device 30 is sealed with the seal resin 80 formed of epoxy resin using the transfer mold method, for example.

Subsequently, the solder ball 70 is mounted on each opening formed in the protection layer 52 using the screen-printing method. Specifically, a solder paste, which is obtained by mixing resin and a solder material to form a paste, is printed on predetermined regions using a screen mask, and the solder paste thus printed is heated up to the solder melting temperature, thereby forming the solder balls 70. In this step, solder used for each solder ball 70 forms an alloy with Ni and Au that form the intermediate layer 64. Accordingly, the intermediate layer 54 is not provided in the form of a Ni/Au layer structure. The intermediate layer 54 is provided in the form of an alloy layer formed of an alloy with Sn, Cu, etc., which are materials that form the solder ball 70 or the wiring layer 60.

With the above-described steps, the semiconductor module 10 according to the embodiment 1 can be manufactured.

The semiconductor module 10 according to the embodiment 1 described above provides the following advantages.

Such an arrangement increases the contact area where each solder ball 70 (external connection electrode) is in contact with the intermediate layer 64 provided to the semiconductor module 10. This increases the strength of the connection between each solder ball 70 and the intermediate layer 64, thereby improving the connection reliability of the solder balls 70. Furthermore, the entire region of each opening formed in the protection layer (photo-solder resist layer) 62 is filled with the solder ball 70, thereby increasing the contact area between each solder ball 70 and the side wall of the corresponding opening formed in the protection layer 62. This increases the strength of the connection between each solder ball 70 and the protection layer 62. Thus, such an arrangement improves the connection reliability of the solder balls 70, thereby improving the connection reliability of the semiconductor module 10.

Furthermore, a portion of the solder ball 70 penetrates into a space between the protection layer 62 and the intermediate layer 64 along the perimeter of each opening. Thus, such an arrangement prevents each solder ball 70 from separating from the opening, thereby further improving the connection reliability of the solder balls 70.

### Embodiment 2

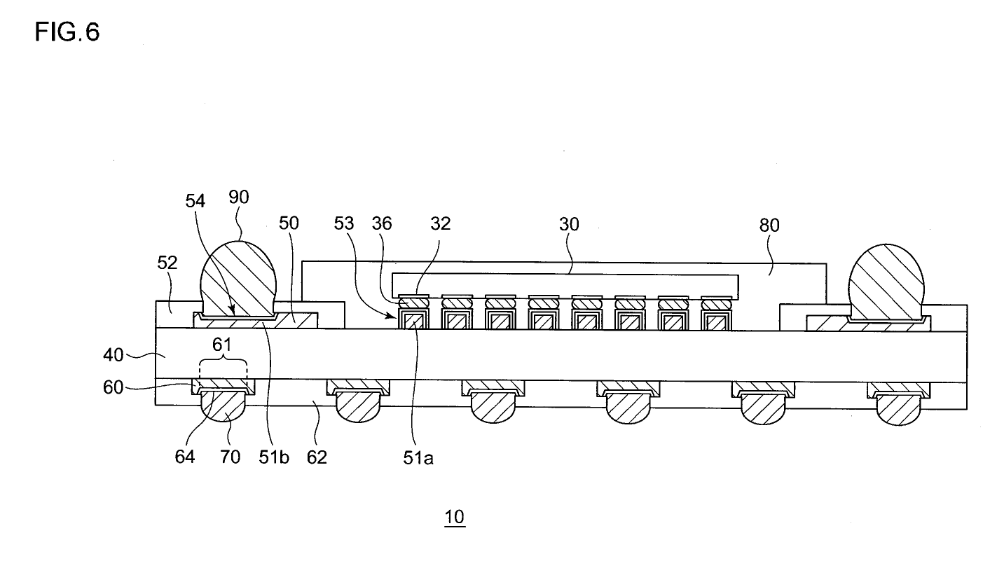

FIG. 6 is a cross-sectional diagram which shows a structure of a semiconductor module according to an embodiment 2. The semiconductor module 10 according to the present embodiment has a so-called package-on-package structure (PoP) which is a three-dimensional package substrate structure in which a package is mounted on another package.

In the present embodiment, the semiconductor device 30 is flip-chip bonded to the device mounting substrate 20 in a state in which the electrode formation face of the semiconductor device 30 is facing downward.

Specifically, the wiring layer 50 includes substrate electrodes 51a used for the flip-chip connection and substrate electrodes 51b used for package-on-package mounting. The surface of each substrate electrode 51a is coated with the Ni/Au layer structure 53. Each device electrode 32 provided to the electrode formation face of the semiconductor device 30 is connected to the Ni/Au layer structure 53 by solder 36. The seal resin 80 is provided in the vicinity of the semiconductor device 30. A part of the wiring layer 50 including the substrate electrodes 51b is positioned outside of the seal resin 80. An opening is formed in the protection layer 52 so as to expose each substrate electrode 51b. A solder ball 90 used for the package-on-package mounting is connected to each opening portion.

An intermediate layer 54 is provided between each solder ball 90 and the corresponding substrate electrode 51b. The solder ball 90 has the same mounting structure as that of the solder ball 70 described in the embodiment 1. The solder ball 90, the protection layer 52, the intermediate layer 54, the substrate electrode 51b, and the wiring layer 50 correspond to the solder ball 70, the protection layer 62, the intermediate layer 64, the external connection region 61, and the wiring layer 60, respectively.

The semiconductor module used as a POP substrate according to the present embodiment improves the connection reliability of the solder balls used for package mounting, as well as improving the connection reliability of the solder balls used for substrate mounting.

### [Application for Mobile Devices]

Next, description will be made regarding a mobile device including the semiconductor module according to the present invention. It should be noted that description will be made regarding an arrangement in which the semiconductor module is mounted on a cellular phone which is a mobile device. However, such a mobile device may be any one of other electronic devices such as personal digital assistances (PDAs), digital video cameras (DVCs), music players, digital still cameras (DSCs), etc.

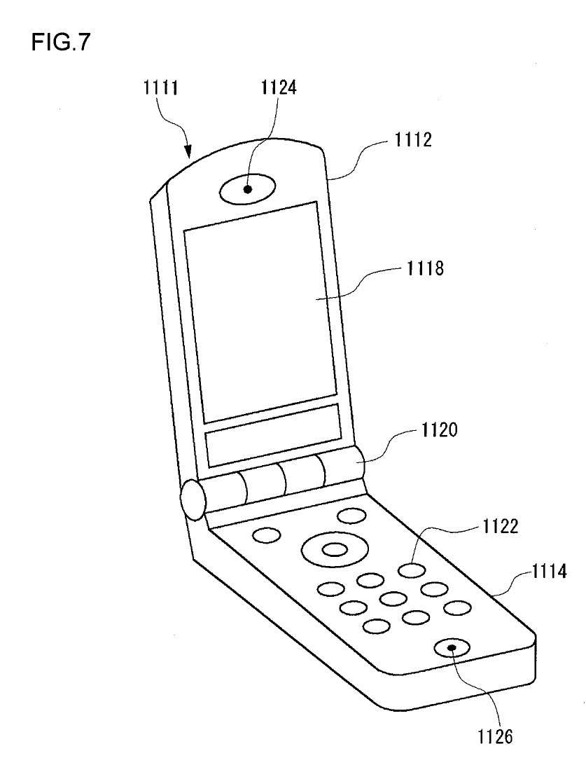

FIG. 7 is a diagram which shows a configuration of a cellular phone according to an embodiment including the semiconductor module 10. A cellular phone 1111 has a configuration in which a first casing 1112 and a second casing 1114 are coupled via a movable unit 1120. The first casing 1112 and the second casing 1114 can be rotated along an axis formed by the movable unit 1120. The first casing 1112 includes a display unit 1118 which displays information such as text messages, images, etc., and a speaker unit 1124. The second casing 1114 includes an operating unit 1122 such as operating buttons, etc., and a microphone unit 1126. The semiconductor module according to any one of the embodiments is mounted within the cellular phone 1111 having such a configuration. It should be noted that the semiconductor module according to the present invention mounted on a cellular phone as described above can be employed as a power supply circuit used to drive each circuit, an RF generating circuit configured to generate RF signals, a DAC, an encoder circuit, a driving circuit for a backlight used as a light source for a liquid crystal panel employed as a display unit of the cellular phone, etc.

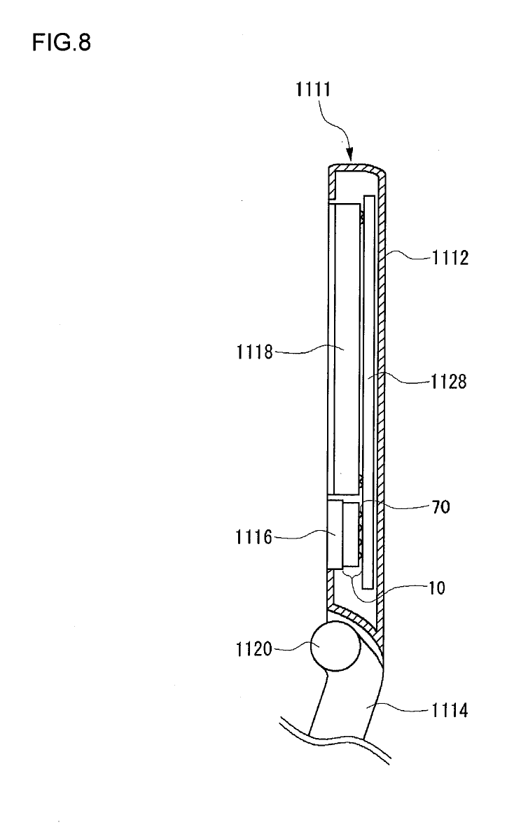

FIG. 8 is a diagram of a partial cross-section which shows the cellular phone shown in FIG. 7 (cross-sectional diagram showing the first casing 1112). The semiconductor module 10 according to an embodiment of the present invention is mounted on a printed substrate 1128 via the solder balls 70, and is electrically connected to the display unit 1118 and so forth via such a printed substrate 1128. Furthermore, a heat sink substrate 1116 such as a metal substrate is provided on the reverse side (the opposite side of the solder balls 70 side) of the semiconductor module 10. For example, such an arrangement prevents heat that occurs in the semiconductor module 10 from being confined in the first casing 1112, and effectively disperses heat to the exterior of the first casing 1112.

The mobile device including the semiconductor module according to an embodiment of the present invention provides the following advantages.

The semiconductor module 10 provides improved connection reliability of the solder balls 70, thereby improving reliability of the operation of the semiconductor module 10. This improves reliability of the operation of the mobile device mounting such a semiconductor module 10.

Heat can be effectively released from the semiconductor module 10 via the heat sink substrate 1116.

Thus, such an arrangement prevents the temperature of the semiconductor module 10 from rising, thereby reducing thermal stress that occurs between the electro-conductive member and the wiring layer. Such an arrangement prevents the electro-conductive member included in the semiconductor module from separating from the wiring layer, thereby improving the reliability (heat resistance) of the semiconductor module 10. As a result, such an arrangement improves the reliability (heat resistance) of the mobile device.

The semiconductor module 10 described above in the embodiment can be formed with a reduced size, thereby permitting a mobile device mounting such a semiconductor module 10 to be designed with a reduced thickness and a reduced size.

The present invention is not restricted to the above-described embodiments. Also, various modifications may be made with respect to the layout and so forth based upon the knowledge of those skilled in this art. Such modifications of the embodiments are also encompassed by the scope of the present invention.

For example, description has been made above in the embodiment 1 regarding an arrangement in which the semiconductor device 30 is wire-bonded. Also, the semiconductor device 30 may be flip-chip bonded. Description has been made above in the embodiments regarding an arrangement in which the insulating resin layer 40, which is a component of the device mounting substrate 20, is provided in the form of a single layer. Also, an arrangement may be made in which the insulating resin layer 40 is provided in the form of a multi-layer structure, and a wiring layer is provided between the adjacent insulating layers.

What is claimed is:

1. A semiconductor module comprising:
an device mounting substrate which comprises
a base material,
a first wiring layer provided on one main surface of the base material,
a second wiring layer provided on the other main surface of the base material, and
a protection layer arranged so as to coat the other main surface of the base material, and provided with an opening through which an external connection region of the second wiring layer is exposed; and
a semiconductor device mounted on the one main surface side of the base material,
wherein the surface of the second wiring layer in the external connection region is positioned closer to the base material side than the bottom of the protection layer on the base material side is to the base material side.

2. A semiconductor module according to claim 1, wherein a space is formed between the bottom of the protection layer on the base material side and the surface of the second wiring layer along the perimeter of the opening,
and wherein the external connection region has a larger area than that of the opening.

3. A semiconductor module according to claim 1, wherein an electro-conductive intermediate layer is formed in the external connection region,
and wherein the surface of the intermediate layer is positioned closer to the base material side than the bottom of the protection layer on the base material side is to the base material side.

4. A semiconductor module according to claim 2, wherein an electro-conductive intermediate layer is formed in the external connection region,
and wherein the surface of the intermediate layer is positioned closer to the base material side than the bottom of the protection layer on the base material side is to the base material side.

5. A semiconductor module comprising:
a base material;
a first wiring layer provided on one main surface of the base material;
a second wiring layer provided on the other main surface of the base material;
a protection layer arranged so as to coat the other main surface of the base material, and provided with an opening through which an external connection region of the second wiring layer is exposed;
an external connection electrode arranged in the external connection region of the second wiring layer; and
a semiconductor device mounted on the one main surface side of the base material,
wherein the surface of the second wiring layer in the external connection region is positioned closer to the base material side than the bottom of the protection layer on the base material side is to the base material side.

6. A semiconductor module according to claim 5, wherein a space is formed between the bottom of the protection layer on the base material side and the surface of the second wiring layer along the perimeter of the opening,
and wherein the space thus formed is filled with the external connection electrode.

7. A semiconductor module according to claim 5, wherein an intermediate layer having higher wettability for the external connection electrode than that of the second wiring layer is provided between the external connection electrode and the wiring layer.

8. A semiconductor module according to claim 6, wherein an intermediate layer having higher wettability for the external connection electrode than that of the second wiring layer is provided between the external connection electrode and the wiring layer.
